(19) United States
(12) Patent Application Publication
(10) Pub. No.: US 2011/0309415 A1
(43) Pub. Date: Dec. 22, 2011

(54) SENSOR USING FERROELECTRIC FIELD-EFFECT TRANSISTOR

(75) Inventors: Tse Nga Ng, Mountain View, CA (US); Rene Jan Peter Kist, Cambridge (GB); Sanjiv Sambandan, Sunnyvale, CA (US)

(73) Assignee: PALO ALTO RESEARCH CENTER INCORPORATED, Palo Alto, CA (US)

(21) Appl. No.: 12/818,999

(22) Filed: Jun. 18, 2010

(51) Int. Cl. H01L 29/84; H01L 21/336

(52) U.S. Cl. 257/254; 438/50; 257/E21.409; 257/E29.324

(57) ABSTRACT

An embodiment is a method and apparatus to sense strain or pressure. A ferroelectric field effect transistor (feFET) structure has a semiconductor layer and a ferroelectric dielectric layer. The feFET structure is capable of sensing strain or pressure.

One disclosed feature of the embodiments is a method to fabricate a strain or pressure sensor. A circuit is printed to form a ferroelectric field effect transistor (feFET) structure having a ferroelectric dielectric layer and a semiconductor layer. The feFET structure is capable of sensing strain or pressure.

### TECHNICAL FIELD

The presently disclosed embodiments are directed to the field of electronics, and more specifically, to sensors.

### BACKGROUND

Large-area light-weight strain gauges are useful to monitor the integrity weight-bearing structures such as bridges, buildings, airplanes, and submarines, or to provide pressure sensors for robots, prosthetics, and other medical devices.

Currently, ferroelectric materials are used to provide voltage response for dynamic strain changes only.

### SUMMARY

One disclosed feature of the embodiments is a method and apparatus to sense strain or pressure. A ferroelectric field effect transistor (feFET) structure has a semiconductor layer and a ferroelectric dielectric layer. The feFET structure is capable of sensing strain or pressure.

One disclosed feature of the embodiments is a method to fabricate a strain or pressure sensor. A circuit is printed to form a ferroelectric field effect transistor (feFET) structure having a ferroelectric dielectric layer and a semiconductor layer. The feFET structure is capable of sensing strain or pressure.

### BRIEF DESCRIPTION OF THE DRAWINGS

Embodiments may best be understood by referring to the following description and accompanying drawings that are used to illustrate various embodiments. In the drawings.

FIG. 1 is a diagram illustrating a system having an area strain/pressure sensor with a flexible substrate according to one embodiment.

FIG. 2 is a diagram illustrating an feFET structure as an array of transistors in a passive matrix configuration according to one embodiment.

FIG. 3 is a diagram illustrating an feFET structure on a flexible wire according to one embodiment.

FIG. 4 is a diagram illustrating an feFET structure in a bottom-gate structure according to one embodiment.

FIG. 5 is a diagram illustrating an feFET structure in a top-gate structure according to one embodiment.

FIG. 6 is a diagram illustrating the characteristics of the source-to-drain current as function of the radius of curvature of the substrate and gate voltage for an feFET transistor according to one embodiment.

FIG. 7 is a diagram illustrating the characteristics of the source-to-drain current as function of the radius of curvature of the substrate and gate voltage for a FET transistor without a ferroelectric dielectric according to one embodiment.

FIG. 8 is a diagram illustrating the characteristics of the source-to-drain current as function of the tensile strain according to one embodiment.

FIG. 9 is a diagram illustrating the characteristics of the change in source-to-drain current under repeated bendings at various values of radius of curvature according to one embodiment.

FIG. 10 is a diagram illustrating the polarization change of a ferroelectric capacitor under strain according to one embodiment.

FIG. 11 is a flowchart illustrating a process to fabricate a strain/pressure sensor according to one embodiment.

FIG. 12 is a flowchart illustrating the process to form a feFET structure having a bottom-gate structure according to one embodiment.

FIG. 13 is a flowchart illustrating a process to form a feFET structure having a top-gate structure according to one embodiment.

FIG. 14 is a diagram illustrating a system having an area strain/pressure sensor without a flexible substrate according to one embodiment.

FIG. 15 is a diagram illustrating an feFET structure as an array of transistors in an active matrix configuration according to one embodiment.

### DETAILED DESCRIPTION

One disclosed feature of the embodiments is a technique to sense strain or pressure. A ferroelectric field effect transistor (feFET) structure has a semiconductor layer and a ferroelectric dielectric layer. The feFET structure is capable of sensing strain or pressure.

One disclosed feature of the embodiments is a method to fabricate a strain or pressure sensor. A circuit is printed to form a ferroelectric field effect transistor (feFET) structure having a ferroelectric dielectric layer and a semiconductor layer. The feFET structure is capable of sensing strain or pressure.

One disclosed feature of the embodiments may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc. One embodiment may be described by a schematic drawing depicting a physical structure. It is understood that the schematic drawing illustrates the basic concept and may not be scaled or depict the structure in exact proportions.

One disclosed feature of the embodiments is a method and apparatus for strain gauge or pressure sensor. Ferroelectric sensors provide strain information for static and dynamic pressure by using the ferroelectric materials as gate dielectrics in transistor structures. The ferroelectric transistors may be made into a mechanically flexible array to conform to surfaces and to provide large-area coverage. The technique measures strain or pressure by monitoring the current change in a ferroelectric field-effect transistor (feFET) under bending. The gate dielectric of a feFET may be fabricated using ferroelectric materials such as Polyvinylidene Fluoride Trifluoroethylene (PVDF-TrFE) polymer, and the transistors may be made with organic semiconductors and may be patterned on plastic or stainless steel substrates to allow for mechanical flexibility. Under bending, the change in feFET current demonstrates strain sensitivity of 200 nA/strain %.

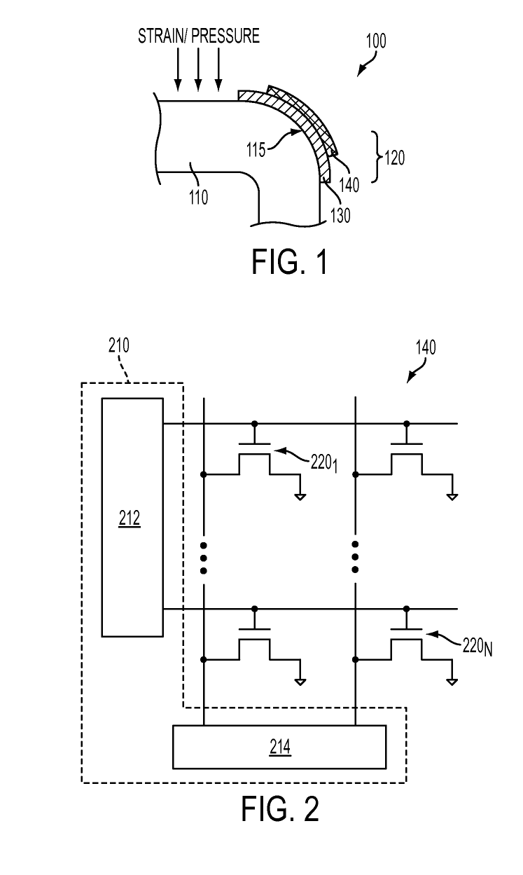

FIG. 1 is a diagram illustrating a system 100 having an area strain/pressure sensor with a flexible substrate according to one embodiment. The system 100 includes a structure 110 and a sensor 120.

The structure 110 may be a structure on which strain or pressure may be applied or a structure which is subject to strain or pressure. The structure 110 may be any weight-bearing structure such as a part or section of a bridge, a building, a vehicle, a medical device, an industrial component, a mechanical assembly, etc. The structure 110 may have a surface 115 that may be flat or curved. When pressure or strain is applied to the structure 110 at, near, or in the vicinity of the surface 115, the surface 115 may be bent or deformed.

The sensor 120 is a pressure or strain sensor or gauge that is attached to the surface 115 to sense or measure the pressure or strain that is applied at, or in the vicinity of, the surface 115. As pressure or strain is applied at, or in the vicinity of, the surface 115, the sensor 120 may also be bent or deformed. The deformation or bending of the sensor 120 causes a current change in the sensor. This current change is s function of the amount of deformation or bending. Accordingly, by measuring or monitoring the current change, a measurement of the strain or pressure may be obtained.

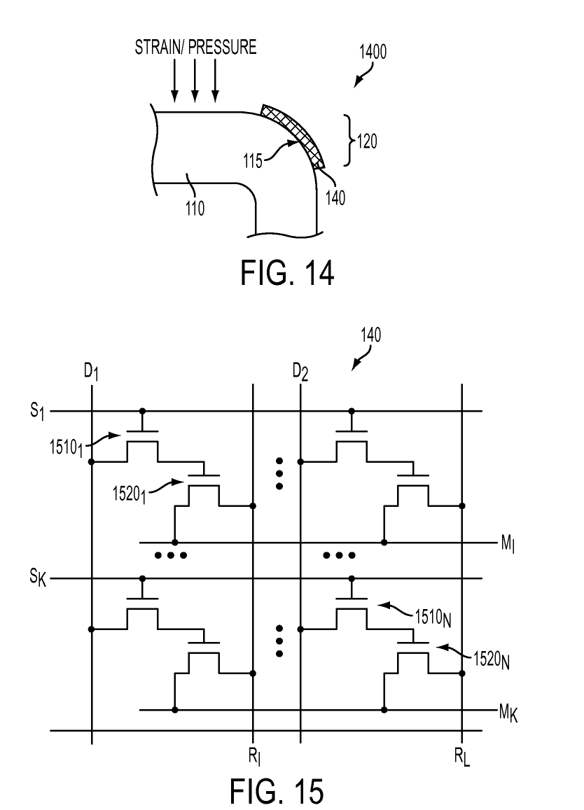

The sensor 120 may be an area sensor or a point sensor. An area sensor is a sensor that covers an area on the surface. The sensor 120 may include a flexible substrate 130 and a ferroelectric FET (feFET) structure 140. For an area sensor, the flexible substrate 130 may be a strip or a patch having an area that is attached to the surface 115. The feFET structure 140 may be an array of transistors or a plurality of transistors that are located at various points on the substrate 130. Typically, an area sensor includes an array of feFET transistors. A point sensor is a sensor that senses the strain/pressure at the particular point or location where the sensor is located. As shown in FIG. 14, the flexible substrate 130 may be optional. The feFET structure 140 may be printed directly on the surface 115.

FIG. 2 is a diagram illustrating the feFET structure 140 as an array of transistors in a passive matrix configuration according to one embodiment. The feFET structure 140 includes a decoder circuitry 210 and a plurality of transistors 220₁ to 220_{N} connected in a pattern or an array of regular pattern. In this passive matrix configuration, as the gate voltage is applied to the horizontal gate line, the entire row is selected.

The decoder circuitry 210 may include a row decoder 212 and a column decoder 214 to address the individual transistor in the plurality of transistors 220₁ to 220_{N}. The array of transistors 220₁ to 220_{N} may be formed in an array of rows and columns of transistors as a two-dimensional matrix, such as in a memory array. Each of the transistors 220₁ to 220_{N} may generate a current that is a function of the amount of bending or deformation at the location where the transistor is located. By addressing the individual transistor through the decoder circuitry 210, the local amount of strain or pressure may be measured. Additional circuits may be incorporated to integrate the local currents to provide the overall measurement of the strain or pressure applied at or in the vicinity of the entire region where the sensor 120 is located.

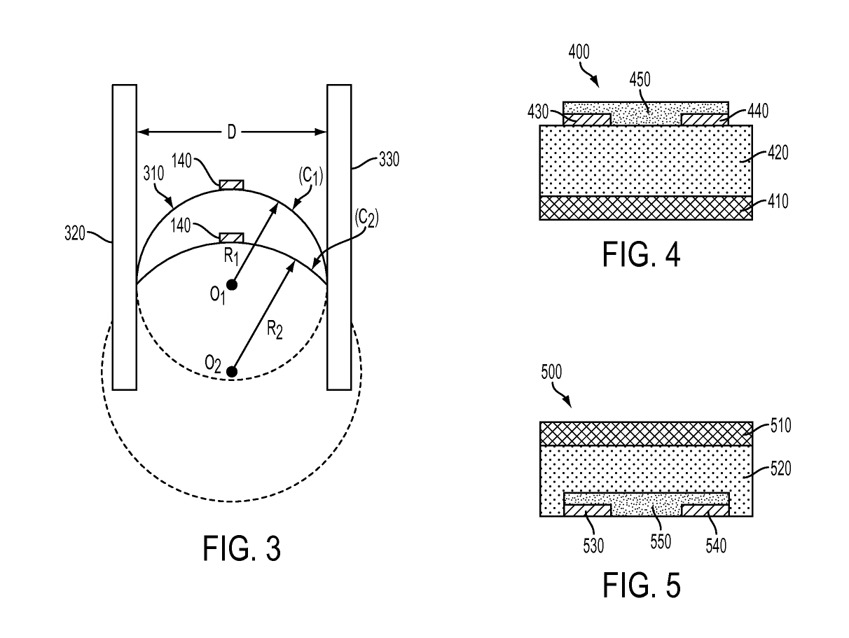

FIG. 3 is a diagram illustrating the feFET structure 140 on a flexible strip according to one embodiment. The feFET structure 140 may be attached to a flexible strip 310 as a sensor to measure pressure applied to the strip 310. This configuration is an illustration of a measurement of pressure that causes the bending of the feFET structure 140.

The strip 310 may be any flexible strip, wire, piece, patch, or any suitable shape and/or form, that is confined by two walls 320 and 330 at two ends located at a distance D of each other. The feFET structure 140 is attached to the strip 310. It may be an individual transistor or an array of transistors. When the two walls 320 and 330 come closer under a force or pressure on both sides to narrow the distance D, the flexible strip 310 may be bent or deformed causing the feFET structure 140 to bend or deform. The bending of the strip 310 causes its radius of curvature R to change. The radius of curvature R may represent a circle that approximates the curve formed by the portion of the strip 310. In other words, the strip 310 may be a chord on a circle. The radius of curvature R may change as the walls 320 and 330 press into its two ends. For example, the circle C₂ having origin O₂ and radius R₂ may be compressed to become circle C₁ having origin O₁ and radius R₁. As D decreases, R is decreased from R₂ to R₁. The decrease of the radius of curvature R causes the current from the feFET structure 140 to decrease. Accordingly, by measuring this current, the amount of pressure or strain applied at the two ends of the flexible strip 310 may be measured.

FIG. 4 is a diagram illustrating the feFET structure 140 in a bottom-gate structure 400 according to one embodiment. The feFET 140 may be fabricated in a bottom-gate configuration. The bottom-gate feFET structure 400 includes a gate electrode 410, a ferroelectric dielectric layer 420, source and drain electrodes 430 and 440, and a semiconductor layer 450. The bottom-gate feFET structure 400 may be fabricated by inkjet printing or by any suitable technique. The surface of the substrate and subsequent printing surfaces may require planarization or surface modification in order to be suitable for printing.

The bottom-gate feFET structure 400 has the gate electrode 410 located at the bottom of the feFET structure 140. The ferroelectric dielectric layer 420 is deposited on the gate electrode by solution deposition. The ferroelectric dielectric layer 420 comprises a polymer or an inorganic ferroelectric composite such as lead zirconate titanate (PZT) thin-film, or a composite of organic and inorganic materials. The source and drain electrodes 430 and 440 are deposited on the ferroelectric dielectric layer 420. They may be deposited by inkjet printing. The semiconductor layer 450 is deposited between the source and drain electrodes 430 and 440 and on the ferroelectric dielectric layer 420. The semiconductor layer may be an organic semiconductor or an inorganic thin-film such as amorphous silicon or nanometer-sized materials such as silicon nanowires.

FIG. 5 is a diagram illustrating the feFET 140 in a top-gate structure 500 according to one embodiment. The feFET 140 may be fabricated in a top-gate configuration. The top-gate feFET structure 500 includes a gate electrode 510, a ferroelectric dielectric layer 520, source and drain electrodes 530 and 540, and a semiconductor layer 550. The top-gate feFET structure 400 may be fabricated by inkjet printing or by any suitable technique. The surface of the substrate and subsequent printing surfaces may require planarization or surface modification in order to be suitable for printing.

The top-gate feFET structure 500 has the gate electrode 510 located at the top of the feFET structure 140. The source and drain electrodes 530 and 540 are printed. The semiconductor layer 550 is deposited between the source and drain electrodes 530 and 540. The semiconductor layer 550 may be an organic semiconductor or an inorganic thin-film such as amorphous silicon or nanometer-sized materials such as silicon nanowires. The ferroelectric dielectric layer 520 is deposited on the source and drain electrodes 530 and 540 and the semiconductor layer 550. The ferroelectric dielectric layer 520 comprises a polymer or an inorganic ferroelectric composite such as lead zirconate titanate (PZT) thin-film. The gate electrode 510 is printed on the ferroelectric dielectric layer 520.

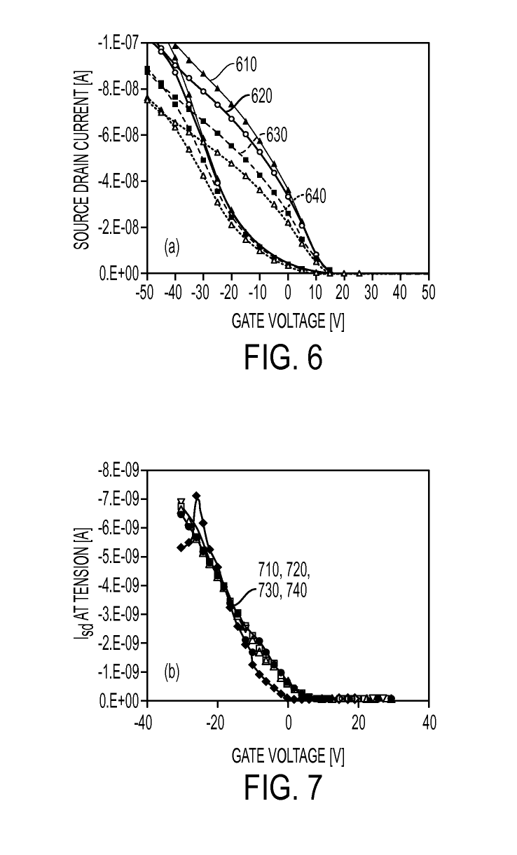

FIG. 6 is a diagram illustrating the characteristics of the source-to-drain current as function of the radius of curvature of the substrate and gate voltage for a feFET transistor according to one embodiment. The characteristics of the source-to-drain current are represented by curves 610, 620, 630, and 640. The curves 610, 620, 630, and 640 correspond to the radius of curvature R of flat, 2 cm, 1 cm, and 0.5 cm. A flat radius of curvature indicates that the surface of the feFET transistor is flat, i.e., not bending. It is noted that the values of the radius of curvature R, the gate voltage, and the source-to-drain current are only for illustrative purposes, and not intended to represent the actual or absolute values.

Each of the curves 610, 620, 630, and 640 exhibits hysteresis as the gate voltage increases and then decreases. Regardless of the hysteresis, the curves show that for a fixed gate voltage, the source-to-drain current I_{sd} decreases as the radius of curvature decreases, or when the surface of the feFET transistor is bent such as when under the influence of pressure. By calibrating the amount of current change with respect to the change of the radius of curvature which in turn is calibrated with respect of the amount of local pressure or strain, a measurement of the local pressure or strain may be achieved.

FIG. 7 is a diagram illustrating the characteristics of the source-to-drain current as function of the radius of curvature of the substrate and gate voltage for a FET transistor without a ferroelectric dielectric according to one embodiment. The characteristics of the source-to-drain current are represented by curves 710, 720, 730, and 740. The curves 710, 720, 730, and 740 correspond to the radius of curvature R of flat, 2 cm, 1 cm, and 0.5 cm. A flat radius of curvature indicates that the surface of the feFET transistor is flat, i.e., not bending. It is noted that the values of the radius of curvature R, the gate voltage, and the source-to-drain current are only for illustrative purposes, and not intended to represent the actual or absolute values.

As seen from the curves, the source-to-drain current changes very little or essentially unchanged until breakdown as the curve of radius R varies from 2 cm to 0.5 cm. In contrast, the curves shown in FIG. 6 show that source-to-drain current change is almost ten times of the change of the source-to-drain current shown in FIG. 7. Accordingly, the use of ferroelectric dielectric in the transistor significantly provides the source-to-drain current change as the function of the amount of bending.

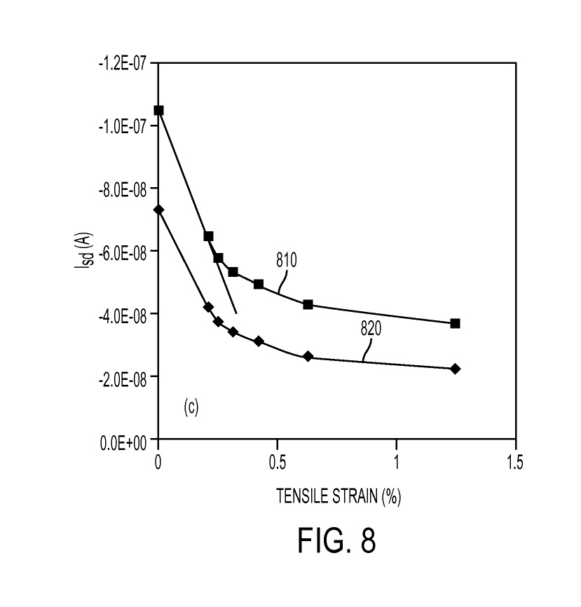

FIG. 8 is a diagram illustrating the characteristics of the source-to-drain current as function of the tensile strain according to one embodiment. The characteristics of the source-to-drain current are represented by curves 810 and 820. The curves 810 and 820 correspond to the readouts of the source-to-drain current at the gate voltage V_{g} at −10V and 0V, respectively. The source-to-drain voltage is at 10V. The feFET transistor under test has a capacitance of 30 nF/cm² having a width W=450 μm and a length L=110 μm. Note that the values for these characteristics are for illustrative purposes only and not intended to represent the actual or absolute values.

The curves 810 and 820 show that the source-to-drain current decreases significantly as the tensile strain increases from 0% to approximately 0.5% and decreases gradually as the tensile strain increases from approximately 0.5% to approximately 1.5%. Overall, the curves 810 and 820 demonstrate that under bending, the change in feFET current exhibits a strain sensitivity of 200 nA/strain %. As seen from these curves, the decrease in transistor current vary with static tension strain non-linearly beyond 0.25% tensile strain, but an approximate linear fit for strain below 0.25% shows a response of 200 nA/strain % for readout gate voltage of −10V. Assuming that polymer has a Young's modulus of 1 GPa, the current response factor is approximately 2 nA per GPa pressure.

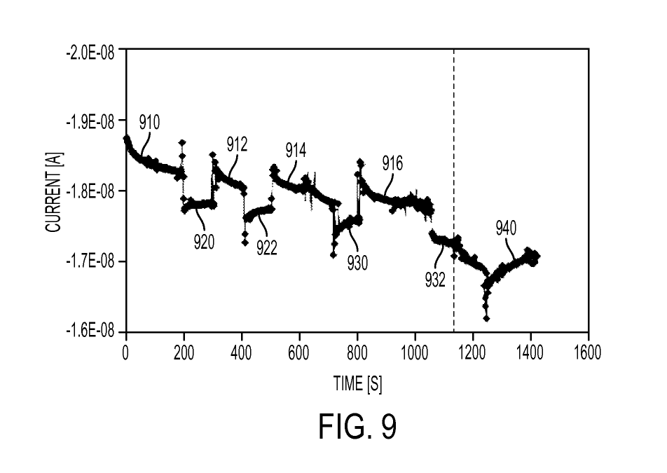

FIG. 9 is a diagram illustrating the characteristics of the change in source-to-drain current under repeated bendings at various values of radius of curvature R according to one embodiment. The characteristics of the change in source-to-drain current include segments of various values of radius of curvature. Segments 910, 912, 914, and 916 correspond to a flat surface. Segments 920 and 922 correspond to R=2 cm. Segments 930 and 932 correspond to R=1.5 cm. Segment 940 corresponds to R=1 cm.

The characteristics of the change in source-to-drain current show that as the substrate is bent from a flat state to a certain radius of curvature, there is a current peak with the dynamic pressure. When the device has settled down from the dynamic pressure, the feFET is still held under static pressure from the bent substrate and the current is observed to be distinguishable from the flat state. Thus, the feFET current provides information for both static and dynamic pressure changes. The origin of the static change may be partially due to the polarization change in the ferroelectric dielectric.

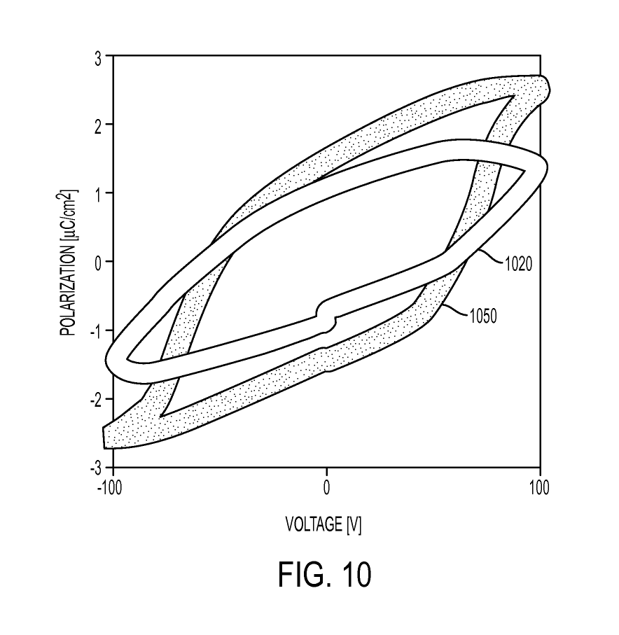

FIG. 10 is a diagram illustrating the characteristics of the polarization change of a ferroelectric capacitor under strain according to one embodiment. The characteristics of the polarization change are represented by curves 1020 and 1050. The curve 1020 shows the polarization as function of the voltage for a flat radius of curvature. The curve 1050 shows the polarization of the capacitor under strain as function of the voltage for a radius of curvature R=2.5 cm. Note that the values for these characteristics are for illustrative purposes only and not intended to represent the actual or absolute values.

The curves 1020 and 1050 show that the capacitor of the ferroelectric dielectric changes when strain/pressure is applied. This capacitor changes results in a decrease in the source-to-drain current. Accordingly, using ferroelectric material as a dielectric layer in a transistor leads to a current change when the transistor is under strain or pressure.

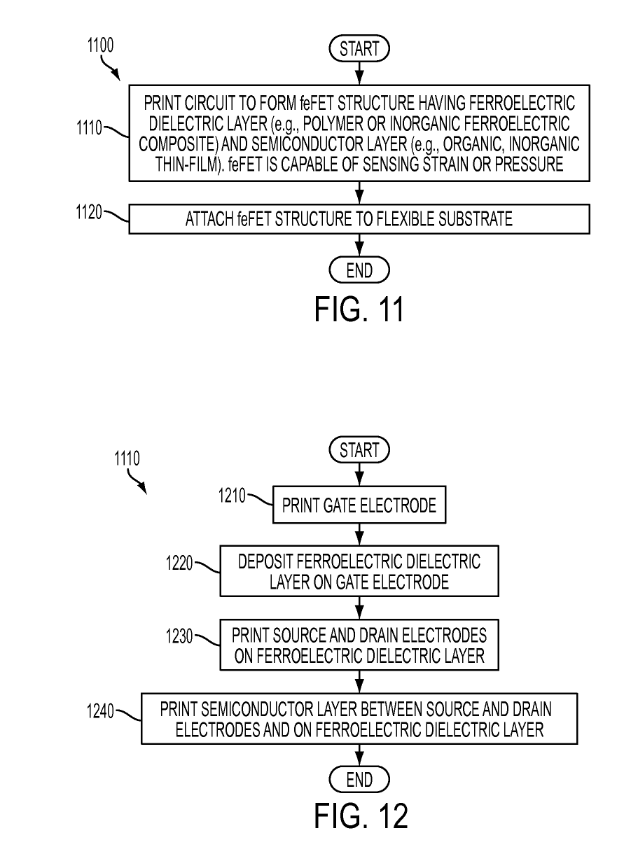

FIG. 11 is a flowchart illustrating a process 1100 to fabricate a strain/pressure sensor according to one embodiment.

Upon START, the process 1100 prints a circuit to form a ferroelectric field effect transistor (feFET) structure (Block 1110). The circuit has a ferroelectric dielectric layer and a semiconductor layer. The feFET structure is capable of sensing strain or pressure. The ferroelectric dielectric layer may include a polymer or an inorganic ferroelectric composite or a composite of organic and inorganic materials. The semiconductor layer may include an organic semiconductor or an inorganic thin-film such as amorphous silicon or nanometer-sized materials such as silicon nanowires. The feFET structure may be fabricated by a bottom-gate structure or a top-gate structure.

Next, the process 1100 attaches the feFET structure to a flexible substrate (Block 1120). The process 1100 is then terminated.

FIG. 12 is a flowchart illustrating the process 1110 to form a feFET structure having a bottom-gate structure according to one embodiment.

Upon START, the process 1110 prints a gate electrode (Block 1210). This may be done using inkjet technology. Next, the process 1110 deposits the ferroelectric dielectric layer on the gate electrode (Block 1220). Then, the process 1110 prints source and drain electrodes on the ferroelectric dielectric layer (Block 1230). Next, the process 1110 prints the semiconductor layer between the source and drain electrodes and on the ferroelectric dielectric layer (Block 1240). The process 1110 is then terminated.

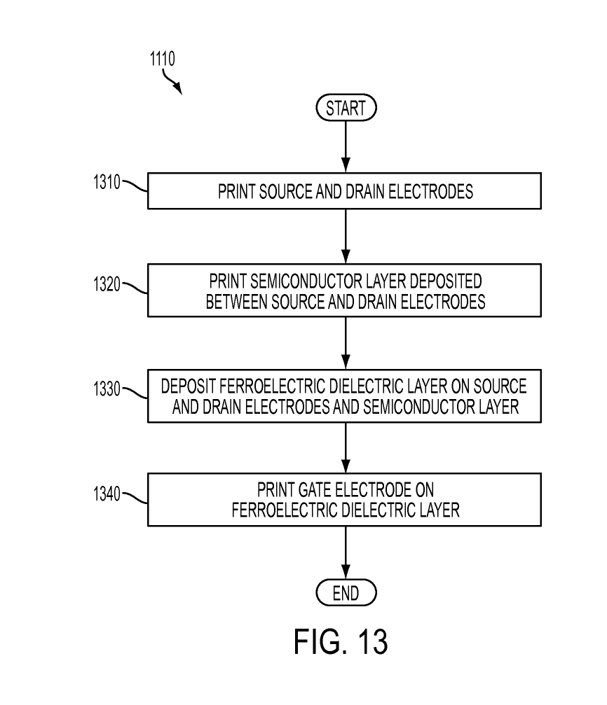

FIG. 13 is a flowchart illustrating a process 1110 to form a feFET structure having a top-gate structure according to one embodiment.

Upon START, the process 1110 prints source and drain electrodes on a substrate (Block 1310). Next, the process 1110 prints the semiconductor layer deposited between the source and drain electrodes (Block 1320). Then, the process 1110 deposits the ferroelectric dielectric layer on the source and drain electrodes and the semiconductor layer (Block 1330). Next, the process 1110 prints a gate electrode on the ferroelectric dielectric layer (Block 1340). The process 1110 is then terminated.

Other embodiments may be possible for the above strain/pressure sensor using feFETs.

FIG. 14 is a diagram illustrating a system 1400 having an area strain/pressure sensor without a flexible substrate according to one embodiment. The system 1400 is similar to the system 100 shown in FIG. 1 except that the sensor 120 does not have the flexible substrate 130. The feFET structure 140 may be printed directly on the surface 115.

FIG. 15 is a diagram illustrating an feFET structure 140 as an array of transistors in an active matrix configuration according to one embodiment. The feFET structure 140 is similar to the structure 140 shown in FIG. 2 except that the matrix is configured as an active matrix. The feFET structure 140 includes a plurality of switches 1510₁ to 1510_{N} connected to a plurality of transistors 1520₁ to 1520_{N}, respectively.

Each of the switches 1510₁ to 1510_{N} may be a transistor or a diode connected to a respective feFET transistor of the plurality of transistors 1520₁ to 1520_{N} the switches 1510₁ to 1510_{N} form corresponding select lines S₁, . . . , S_{K} and data lines _{D1,} . . . , D_{L}. The feFET transistors 1520₁ to 1520_{N} form corresponding bus lines M₁, . . . M_{K} and read-out lines R₁, . . . , R_{L}. A gate voltage may be specifically applied to an individual feFET gate through the select line (e.g., S₁) and the data line (e.g., D₁). In this manner, more specific addressing may be achieved.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. An apparatus comprising:
a semiconductor layer; and
a ferroelectric dielectric layer formed together with the semiconductor layer into a ferroelectric field effect transistor (feFET) structure capable of sensing strain or pressure.

2. The apparatus of claim 1 further comprising:
a flexible substrate attached to the feFET structure.

3. The apparatus of claim 2 wherein the flexible substrate is one of a flexible wire, a strip, and an area patch.

4. The apparatus of claim 1 wherein the ferroelectric dielectric layer comprises a polymer or an inorganic ferroelectric composite or a composite of organic and inorganic materials.

5. The apparatus of claim 1 wherein the semiconductor layer is an organic semiconductor or an inorganic thin film.

6. The apparatus of claim 1 wherein the feFET structure has a bottom-gate structure or a top-gate structure.

7. The apparatus of claim 6 wherein the bottom-gate structure comprises:
a gate electrode;
the ferroelectric dielectric layer deposited on the gate electrode;
source and drain electrodes deposited on the ferroelectric dielectric layer; and
the semiconductor layer deposited between the source and drain electrodes and on the ferroelectric dielectric layer.

8. The apparatus of claim 6 wherein the top-gate structure comprises:
source and drain electrodes;
the semiconductor layer deposited between the source and drain electrodes;
the ferroelectric dielectric layer deposited on the source and drain electrodes and the semiconductor layer; and
a gate electrode deposited on the ferroelectric dielectric layer.

9. The apparatus of claim 7 wherein source-drain current decreases under tension when radius of curvature of the flexible substrate is reduced.

10. The apparatus of claim 8 wherein source-to-drain current decreases under tension when radius of curvature of the flexible substrate is reduced.

11. The apparatus of claim 1 wherein the feFET structure comprises an array of transistors, each of the transistors having a ferroelectric dielectric layer and a semiconductor layer.

12. A method comprising:
printing a circuit to form a ferroelectric field effect transistor (feFET) structure having a ferroelectric dielectric layer and a semiconductor layer, the feFET structure capable of sensing strain or pressure.

13. The method of claim 12 further comprising:
attaching feFET structure to a flexible substrate.

14. The method of claim 12 wherein the ferroelectric dielectric layer comprises a polymer or an inorganic ferroelectric composite or a composite of organic and inorganic materials.

15. The method of claim 12 wherein the semiconductor layer comprises an organic semiconductor or an inorganic thin film.

16. The method of claim 12 wherein printing the circuit comprises:
printing a gate electrode;
depositing the ferroelectric dielectric layer on the gate electrode;
printing source and drain electrodes on the ferroelectric dielectric layer; and
printing the semiconductor layer between the source and drain electrodes and on the ferroelectric dielectric layer.

17. The method of claim 12 wherein printing the circuit comprises:
printing source and drain electrodes;
printing the semiconductor layer deposited between the source and drain electrodes;
depositing the ferroelectric dielectric layer on the source and drain electrodes and the semiconductor layer; and
printing a gate electrode on the ferroelectric dielectric layer.

18. A system comprising:
a structure having a curved surface; and
a sensor attached the curved surface to sense pressure applied to the structure, the sensor comprising an array of transistors, each of the transistors having:
a semiconductor layer, and
a ferroelectric dielectric layer formed together with the semiconductor layer into a ferroelectric field effect transistor (feFET) structure attached to the flexible substrate to sense the pressure.

19. The system of claim 18 wherein the sensor further comprising:
a flexible substrate attached to the array of transistors.

20. The system of claim 19 wherein each of the transistors has a bottom-gate structure or a top-gate structure.
